(19) United States
(12) Patent Application Publication
(10) Pub. No.: US 2016/0216333 A1
(43) Pub. Date: Jul. 28, 2016

(54) SYSTEM AND METHOD FOR INDUCTION MOTOR ROTOR BAR MAGNETIC FIELD ANALYSIS

(71) Applicant: Brandon & Clark, Inc., Lubbock, TX (US)

(72) Inventor: Scott W. Clark, Lubbock, TX (US)

(21) Appl. No.: 14/877,615

(22) Filed: Oct. 7, 2015

Related U.S. Application Data
(60) Provisional application No. 62/107,100, filed on Jan. 23, 2015.

(51) Int. Cl. G01R 31/34; G01D 5/20

(52) U.S. Cl. CPC G01R 31/34; G01D 5/2033

(57) ABSTRACT

A system for magnetic field testing comprising a magnetic field generation device configured to generate a magnetic field in a rotor, a magnetic field measurement device configured to measure a magnetic field at a predetermined position on the rotor, a drive mechanism configured to rotate the rotor and a test system configured to record the magnetic field as a function of an angular position of the rotor.

### RELATED APPLICATIONS

The present application claims priority to U.S. Provisional Patent Application No. 62/107,100, filed Jan. 23, 2015, which is hereby incorporated by reference for all purposes as if set forth herein in its entirety.

### TECHNICAL FIELD

The present disclosure relates generally to motor testing, and more specifically to a system and method for induction motor rotor testing.

### BACKGROUND OF THE INVENTION

Induction motor rotor testing includes magnetic field testing that is used in conjunction with manual placement of a field generator and a visual magnetic field indicator, which is inaccurate, hazardous and which fails to create a record of the test results.

### SUMMARY OF THE INVENTION

A system for magnetic field testing is provided. The system includes a magnetic field generation device configured to generate a magnetic field in a rotor, such as by placing a magnetic flux guide with a winding adjacent to the rotor and with a predetermined air gap, and by causing a current to flow in the winding. A magnetic field measurement device is configured to measure a magnetic field at a predetermined position on the rotor, such as at the same radial location of the rotor as the magnetic field generation device, but at a different axial location from the magnetic field generation device. A drive mechanism is configured to rotate the rotor, such as at a predetermined speed that is no faster than a response time of the magnetic field measurement device. A test system is configured to record the magnetic field as a function of an angular position of the rotor, and to analyze the recorded data to identify damaged or broken rotor bars, such as by comparing the magnetic field at a given angular position to a predetermined percentage of an average maximum value for each of a plurality of rotor bars.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views, and in which:

FIG. 1 is a diagram of a system for rotor field analysis testing, in accordance with an exemplary embodiment of the present disclosure;

FIG. 2 is a diagram of a system for rotor field measurement and analysis, in accordance with an exemplary embodiment of the present disclosure;

FIG. 3 is a flow chart of an algorithm for rotor field analysis, in accordance with an exemplary embodiment of the present disclosure; and

FIG. 4 is a diagram of a magnetic field measurement waveform in accordance with an exemplary embodiment of the present disclosure.

### DETAILED DESCRIPTION OF THE INVENTION

In the description that follows, like parts are marked throughout the specification and drawings with the same reference numerals. The drawing figures might not be to scale and certain components can be shown in generalized or schematic form and identified by commercial designations in the interest of clarity and conciseness.

Detection of defects in induction machine rotor bars for unassembled motors is required in order to evaluate machines that are being repaired, as well as to fulfill incremental quality assurance checks in the manufacture of new machines. The ability to detect rotor bar defects prior to the completion of motor assembly is important in order to be able to repair motors quickly and to assure the quality of newly manufactured machines. For example, detecting rotor bar defects early in the work process aids in timely and high quality construction of induction motors. Rotor bar defects that are not found at this early stage might remain undetected until load is applied to the motor after installation, at which time the defect can result in catastrophic failure.

Rotor bar defects can be grouped into two categories—minor defects and major defects. Minor defects can be caused by poor rotor bar to end ring connections, metallurgical flaws or other causes. Major defects can be caused by broken rotor bars (where the rotor bar has become completely disconnected from its end ring) or other causes. Existing techniques for evaluating rotor bar state with a rotor separated from its host stator include a simple visual inspection, which may detect some major defects, but which often fails to detect minor defects. Cast rotors are particularly difficult to evaluate, because the rotor bar to end ring interface is usually unavailable for visual inspection.

Beyond visual inspections, other techniques that exist to detect rotor bar defects include dye penetration tests, ultrasonic testing, growler-hacksaw tests, growler-iron fillings tests, growler-magnetic field viewing film tests, high current excitation tests and digital low resistance ohm-meter (DLRO) tests. Some of these tests present a substantial risk of arc-flash to the operator, because they require contact to an energized rotor as part of the testing procedure. Some of these tests run the risk of damaging the rotor permanently, such as the high current excitation tests, which can create temperatures capable of creating a mechanical deformation of the rotor shaft.

Many facilities use a growler apparatus to induce a current in rotor bars under evaluation and use magnetic viewing film to detect the presence of a magnetic field for each rotor bar. The absence of a magnetic field when a growler is applied to the rotor represents a major rotor bar defect, such as a broken rotor bar. Though considered one of the advanced rotor bar defect detection techniques, the use of a magnetic field viewing film cannot detect minor rotor bar defects. Furthermore, all growler techniques expose the test operator to substantial electrical shock and arc flash hazards. Only one of the existing rotor bar defect detection techniques can identify a minor rotor bar defect, namely, the DLRO test. While the DLRO test is effective for minor defect detection, it cannot be universally applied with all rotor designs, such as cast rotors, without modification to the rotor to allow for the connection of the test apparatus.

These previously-known methods for detecting rotor bar defects in unassembled motors lacked the sensitivity to find both major and minor defects in both cast and fabricated rotors, failed to provide quantifiable test results, and created an arc-flash safety hazard. A process of direct magnetic field analysis in accordance with the present disclosure can allow induced current measurements in a rotor that has been separated from its stator to be examined, yielding a high-resolution fingerprint of a rotor's magnetic field. The disclosed process can identify both major and minor rotor bar defects in a repeatable and quantifiable manner that is appropriate for numerical evaluation without arc-flash safety hazards.

In accordance with the present disclosure, direct magnetic field measurements of a rotor are performed to evaluate rotor bar defects. The present disclosure can generate a digital fingerprint of the rotor that can be numerically evaluated to detect both major and minor rotor bar defects. The digital rotor fingerprint is unique to each rotor and can be generated over the lifecycle of the motor and compared with prior digital rotor fingerprints for each rotor, to evaluate rotor health and identify developing damage. This process of rotor field analysis (RFA) can be performed with the rotor in an automated test stand and with no operator contact with the rotor required. RFA testing solves many of the problems associated with unassembled rotor bar defect detection, provides a highly sensitive test with recordable results, and reduces the risk of damage to the rotor and exposure of testing personnel to electrical hazards.

RFA testing is performed by directly measuring the magnetic field produced by each rotor bar when the rotor is exposed to a time-varying magnetic field, such as a single phase 60 (Hz) field or other suitable frequency field. Likewise, multiple frequency components, time varying frequency components or other suitable time-varying magnetic fields can also or alternatively be used. Unlike traditional growler testing, the magnetic field induction coil is not placed into direct contact with the rotor, but is instead held at a predetermined air gap, to allow the rotor to be rotated slowly during testing. Maintaining a consistent air gap for the magnetic field induction coil is important, to allow the test to be repeatable and to allow rotor fingerprint comparisons. A balancing machine can be used to provide a platform for RFA analysis. A precision magnetometer can be used for rotor magnetic field detection, such as one that includes a transverse or tangential probe that is oriented with respect to the rotor bars. Axial and omnidirectional probes might not be applicable with RFA. The magnetometer can provide a wide frequency range response, such as from DC to 50 (kHz) or higher or other suitable ranges. Even if the magnetic field induction coil operates at a single frequency such as 60 (Hz), the induced harmonics associated with the disclosed RFA system testing can result in high frequency components that make high frequency response magnetometers applicable. With a transverse probe, the magnetic B field can be tangential to the probe surface for maximum probe response, which can also yield a large detection signal when the probe is directly above a rotor bar and a low signal when the probe is centered directly between rotor bars.

The probe can be positioned above an area of the rotor where rotor core steel is present. If the probe is placed above an area without rotor core steel, such as an air duct area or an area towards the end ring on a fabricated rotor, the magnetic field strength variation between rotor bars may not be pronounced enough to detect minor defects. The placement of the probe within the core steel envelope allows for the measurement of a consistently shaped magnetic field pattern that transitions from being in line with the probe to being tangential to the probe, which can provide high sensitivity for bar detection and analysis.

With the magnetometer probe situated appropriately, the rotor can be rotated by a belt and gearbox coupled motor or other suitable driving mechanisms. The speed of rotation can be matched to an acquisition speed of associated magnetometer hardware. Because the acquisition speed can be slower than conventional drive motors installed on balancing machines, a special drive mechanism may be required. Typical rotation rates required for RFA testing are on the order of 0.2 (rpm). Magnetometer readings can be recorded with suitable data acquisition hardware for post-test numerical analysis, such as high resolution digital data generation and recording equipment. A high accuracy magnetometer allows for weak or minor rotor bar damage to be detected, and has benefits beyond accuracy and repeatability.

With traditional growler techniques, the magnetic field detection equipment needs to be placed on the top of a rotor with the associated growler on the bottom of the rotor. This opposing sides topology is the least efficient topology possible, requiring large induced fields to create detectable rotor bar magnetic field on the opposite side of the rotor. In contrast, with the RFA technique, it is not necessary to measure the induced rotor bar field on an opposite side of the rotor, which allows for a reduction in magnetic field induction coil power. Although the probe positioning of the magnetometer is co-located on the same side of the rotor as the inducer coil, the probe should be placed as far away axially along the rotor from the inducer coil as possible. The inducer coil can be placed on one axial end of the rotor, and the probe on the opposite axial end, with both aligned and centered over the same initial rotor bar.

The use of a consistent setup pattern with set inducer and probe positioning guidelines along with consistent rotation direction with respect to the drive end of the rotor allows for identification of suspect rotor bar defects in the recorded rotor field analysis data and the subsequent physical identification of those suspected defects on the rotor. With a proper configuration, an oscillating magnetic field signature can be provided as each bar passes the magnetometer probe. The required inducing field strength is much smaller than typically required with growler testing, due to the sensitivity of the magnetometer and the improved efficiency of the probe position relative to the inducer coil. Using the disclosed RFA technique, no human contact with the rotor is required during testing, which minimizes the test operators' exposure to electrical shock hazards and arc-flash hazards.

Automated numerical analysis of the recorded magnetometer waveform can also be provided, using the rotor bar magnetic field fingerprint and the designed allowable bar to bar magnetic field variance, which can be determined by the repair or manufacture facility. The RFA test set can use a bar index marking tracking technique to determine when a 360 degree fingerprint is complete. After obtaining a 360 degree fingerprint, a peak and trough identification algorithm can be applied. For each trough pair and associated peak, an average trough magnitude to peak magnitude value can be calculated. The maximum of all troughs to peak values can be used as the baseline to compare all trough-to-peak bar field readings using a supplied allowed variance. Bar field readings that fall below the defined minimum variance can be marked as having suspected minor defects, based on the RFA fingerprint. Further analysis can then be performed to find the signatures of major bar defects. For each peak found in the RFA fingerprint, a peak-to-peak separation distance can also be calculated. The smallest peak-to-peak separation value can be used as the baseline to compare all peak-to-peak separation calculations. If any peak-to-peak separation calculations exceed the baseline by 25%, then the mid-point of that peak-to-peak separation may indicate a spatial location of a broken bar. With the minor and major defect calculation processes, each bar in a rotor can be identified and its electrical performance relative to the other bars can be analyzed and reported.

In addition to minor and major defect detection via RFA, rotor field analysis can be used as a method of developing a unique fingerprint for a rotor. The fingerprints can be compared with subsequent fingerprints in the future to determine if a progressive rotor bar failure is occurring even though the rotor bar magnetic field performance is still within the bar to bar comparative limits. A database of rotor fingerprints can be used to allow for further statistical comparisons. With a large database of fingerprints to draw from, first time fingerprints can be compared to similar motors in a database for enhanced rotor bar defect detection.

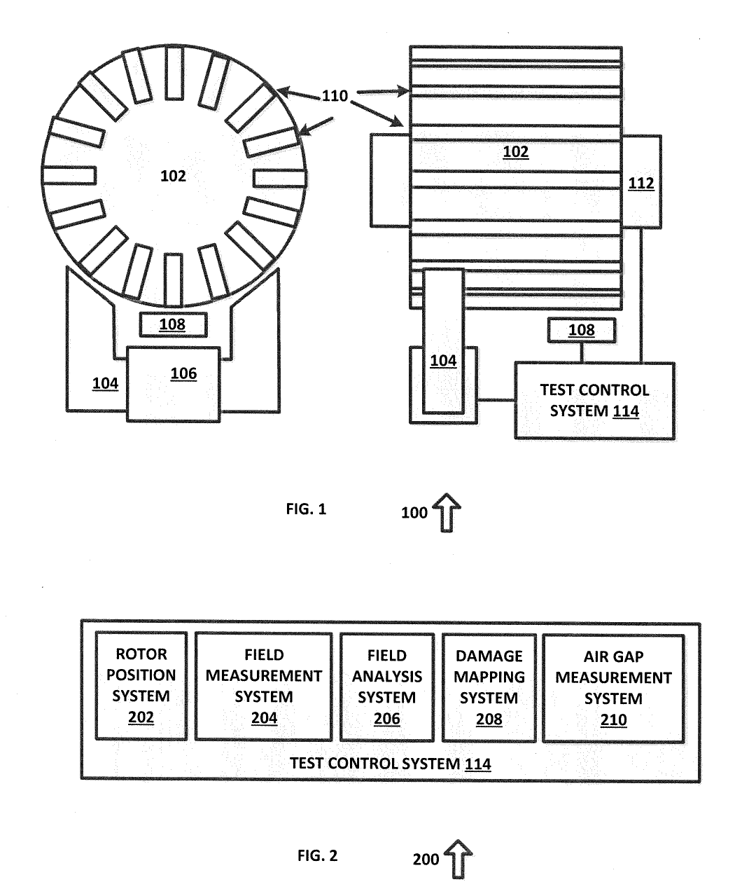

FIG. 1 is a diagram of a system 100 for rotor field analysis testing, in accordance with an exemplary embodiment of the present disclosure. System 100 includes rotor 102, magnetic flux guide 104, coil 106, sensor 108, rotor bars 110, motor 112 and test control system 114.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

Rotor 102 and rotor bars 110 are part of a device under test, such as during original manufacture, repair, remanufacture or at other suitable times. Rotor 102 can be made from magnetic steel or other suitable materials, such as from a single solid casting, from multiple solid components, from laminations or in other suitable manners. Rotor bars 110 can be made from copper or other suitable materials, such as from copper bars, from stranded copper conductors, from hollow air or water cooled copper conductors, or in other suitable manners. Rotor bars 110 can be encased in insulation and then placed in slots in rotor 102, either before the insulation materials are cured, after the insulation materials are cured or in other suitable manners.

Magnetic flux guide 104 can be made from magnetic steel, such as using a single solid piece, multiple pieces, laminations or other suitable materials. Coil 106 can be a wound copper coil or other suitable coils that are used to carry a time varying current to induce a magnetic field in magnetic flux guide 104.

Sensor 108 can be a transverse or tangential magnetometer probe or other suitable sensors that can detect magnetic fields across a wide range of magnitudes. In one exemplary embodiment, sensor 108 can be a scalar magnetometer, a vector magnetometer, a stationary or rotating coil magnetometer, a Hall effect magnetometer, a magnetoresistive devices, a fluxgate magnetometer, a superconducting quantum interference device magnetometer, a vibrating sample magnetometer, a pulsed field extraction magnetometer, a torque magnetometer, a Faraday force magnetometer, an optical magnetometer, a proton precession magnetometer, an Overhauser effect magnetometer, a cesium vapor magnetometer, a potassium vapor magnetometer, other suitable magnetometers or a combination of suitable magnetometers.

Motor 112 can be a belt and gearbox coupled motor, a stepper motor, a servo motor, an AC motor or other suitable motors that are configured to rotate rotor 102 at a suitable speed, such as 0.02 to 2 RPM or at other suitable speeds. In one exemplary embodiment, motor 112 can be part of an automated test stand or can be implemented in other suitable manners.

Test control system 114 is coupled to coil 106, sensor 108 and motor 112, and can coordinate the performance of rotor field analysis testing. In one exemplary embodiment, test control system 114 can receive or generate rotor position indexing data that can be used to identify a rotor bar position relative to a rotor body or other rotor bars, can activate and deactivate motor 112, can energize and de-energize coil 106, can record digital or analog data from sensor 108 with associated time and identification data, can analyze the recorded data, can compare the recorded data to previously stored data and can perform other suitable functions.

In operation, system 100 can generate rotor field analysis data to identify damaged or broken rotor bars during rotor manufacturing or repair, to create a digital fingerprint of the rotor for future use and for other suitable purposes. System 100 allows rotor field analysis testing to be performed in a repeatable manner and with no risk to personnel.

FIG. 2 is a diagram of a system 200 for rotor field measurement and analysis, in accordance with an exemplary embodiment of the present disclosure. System 200 includes test control system 114 and rotor position system 202, field measurement system 204, field analysis system 206, damage mapping system 208 and air gap measurement system 210, each of which can be implemented in hardware or a suitable combination of hardware and software.

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications, on one or more processors (where a processor includes a microcomputer or other suitable controller, memory devices, input-output devices, displays, data input devices such as a keyboard or a mouse, peripherals such as printers and speakers, associated drivers, control cards, power sources, network devices, docking station devices, or other suitable devices operating under control of software systems in conjunction with the processor or other devices), or other suitable software structures. In one exemplary embodiment, software can include one or more lines of code or other suitable software structures operating in a general purpose software application, such as an operating system, and one or more lines of code or other suitable software structures operating in a specific purpose software application. As used herein, the term “couple” and its cognate terms, such as “couples” and “coupled,” can include a physical connection (such as a copper conductor), a virtual connection (such as through randomly assigned memory locations of a data memory device), a logical connection (such as through logical gates of a semiconducting device), other suitable connections, or a suitable combination of such connections.

Rotor position system 202 reads and stores indexing data to determine a rotor position. In one exemplary embodiment, rotor position system 202 can detect an indexing device, such as a magnetic sensor, an optical indicator, or other suitable data that can be used for rotor bar location, for indexing the rotor bars of a rotor under test. In another exemplary embodiment, rotor position system 202 can receive user-entered data that is associated with a rotor bar, such as in response to a generated sensor waveform or in other suitable manners. Rotor position system 202 can assign a rotor bar number or identifier to each of a plurality of rotor conductor bars on a rotor under test, and perform other suitable functions.

Field measurement system 204 receives sensor data from a magnetometer or other suitable devices, stores the sensor data, displays the sensor data and performs other suitable functions. In one exemplary embodiment, field measurement system 204 can provide energization voltage and current to a sensor system, can read digital or analog data from a sensor system, can record electrical signals from a sensor system, can calibrate a sensor system and can perform other suitable functions. Likewise, field measurement system 204 can use different frequency excitation voltages to determine whether damage exists on a given rotor bar, can measure a frequency spectrum of the magnetic field to determine whether damage exists, or can use other suitable measurement techniques.

Field analysis system 206 receives field measurement data and analyzes the field measurement data to identify a maximum and minimum reading for each rotor bar, a maximum and minimum reading for all rotor bars of a rotor under test, to identify an angular position for each rotor bar, to determine an angular separation for each rotor bar, to identify damaged and broken rotor bars, to compare field measurement data to previously recorded field measurement data, and for other suitable purposes. Field analysis system 206 can analyze analog or digital data, can generate waveform displays and text reports, and can perform other suitable functions. Likewise, field analysis system 206 can analyze fields measured at different excitation frequencies to determine whether damage exists on a given rotor bar, can analyze a frequency spectrum of the magnetic field to determine whether damage exists, or can use other suitable analytical techniques.

Damage mapping system 208 receives data from field analysis system 206 and generates damage mapping data to allow an operator to identify damaged or broken rotor bars or other damaged rotor components. In one exemplary embodiment, damage mapping system 208 can identify damaged and broken rotor bars by number, by an indexed angular position, can provide control data to cause a drive motor to advance a rotor under test to a predetermined position to allow a damaged or broken rotor bar to be inspected and can perform other suitable functions.

Air gap measurement system 210 measures and records air gap data for an air gap between a rotor under test and a magnetic field induction coil as a function of rotor position. In one exemplary embodiment, air gap measurement system 210 can use optical data, electrical data, acoustic data or other suitable data to measure an average air gap as a function of rotor position, to allow magnetic field measurements made during a rotor field analysis test to be calibrated and consistent with prior magnetic field measurements.

In operation, system 200 allows rotor field analysis testing to be performed on a rotor under test to identify damaged or broken rotor bars, to create a fingerprint of the rotor under test and for other suitable purposes. System 200 automates a test apparatus and helps to protect personnel from exposure to dangerous voltage levels.

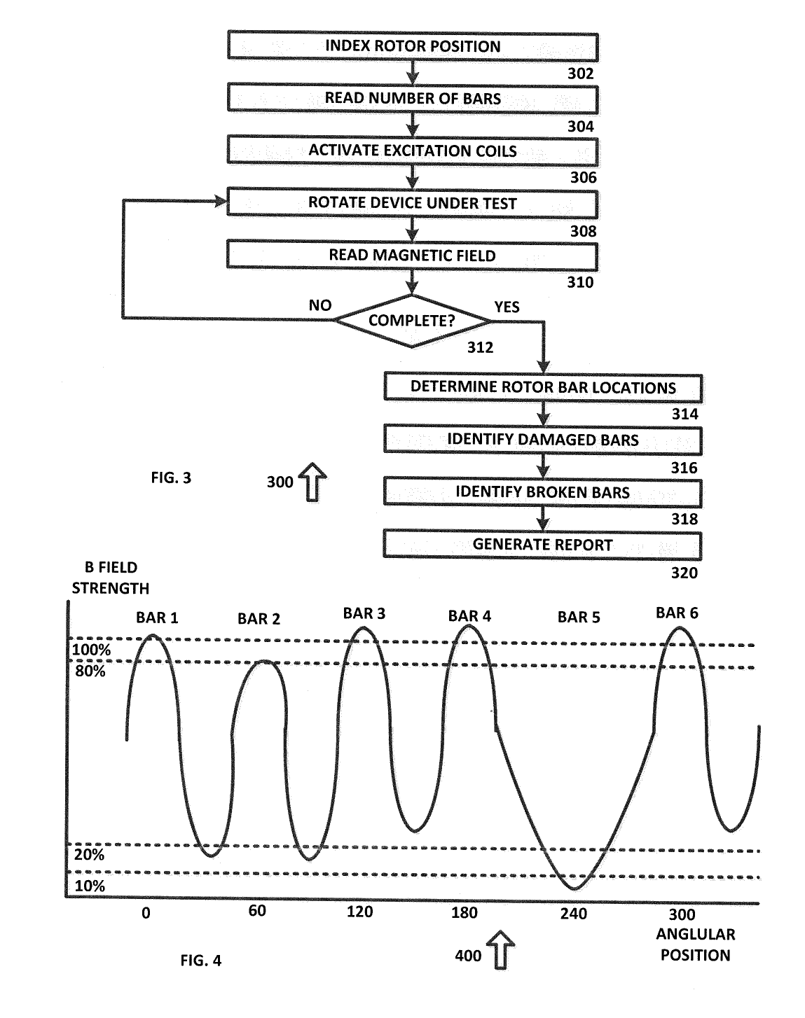

FIG. 3 is a flow chart of an algorithm 300 for rotor field analysis, in accordance with an exemplary embodiment of the present disclosure. Algorithm 300 can be implemented in hardware or a suitable combination of hardware and software.

Algorithm 300 begins at 302, where a rotor position is indexed. In one exemplary embodiment, a rotor can include a predetermined number of rotor bars, a rotor bar indexing device or mark or other suitable indexing features, and the rotor position can be determined at 302, such as by activating a magnetic or optical sensor while causing the rotor under test to rotate on a test stand or in other suitable manners. Likewise, a user can enter an indexing position using a data entry device, or other suitable processes can also or alternatively be used. The algorithm then proceeds to 304.

At 304, a number of rotor bars is read. In one exemplary embodiment, the number of rotor bars can be read using magnetic or optical sensors, a user can enter a number of rotor bars using a data entry device or other suitable processes can also or alternatively be used. The algorithm then proceeds to 306.

At 306, magnetic field excitation coils are energized, such as to generate a test magnetic flux field, to measure an air gap or for other suitable purposes. In one exemplary embodiment, the magnetic field excitation coils of a rotor field analysis device can be energized at different levels, using different frequencies or in other suitable manners. The algorithm then proceeds to 308.

At 308, the rotor under test is rotated. In one exemplary embodiment, the rotor under test can be rotated at a suitable test speed, such as a speed between 0.1 and 2 revolutions per minute, can be rotated using a stepper motor, or can be rotated in other suitable manners. The algorithm then proceeds to 310.

At 310, a magnetic field sensor reading is made and recorded. In one exemplary embodiment, a magnetometer sensor can be used to generate an electrical signal that is proportional to a magnetic field at the magnetometer. The magnetometer can be a transverse or tangential probe, the measurements can be digital or analog, and other suitable sensor readings can also or alternatively be made. The algorithm then proceeds to 312.

At 312, it is determined whether the magnetic field measurements are complete. If the measurements are not complete, the algorithm returns to 308, otherwise the algorithm proceeds to 314.

At 314, rotor bar locations corresponding to the magnetic field measurements are determined. In one exemplary embodiment, successive maximum and minimum magnetic field measurements can be identified by waveform analysis, angular distances between adjacent magnetic field measurements can be identified based on the difference between two adjacent maxima or minima, and other suitable data processing procedures can be used to identify rotor bar locations. The algorithm then proceeds to 316.

At 316, damaged rotor bars are identified. In one exemplary embodiment, the range of maximum and minimum magnetic field strengths can be identified, and stochastic thresholds can be determined by comparing measured magnetic field data values from known damaged rotor bars to the maximum and minimum values for the associated rotors, such as 80% of an average value, 80% of a maximum value and so forth. The algorithm then proceeds to 318.

At 318, broken rotor bars are identified. In one exemplary embodiment, the range of maximum and minimum magnetic field strengths can be identified, and stochastic thresholds can be determined by comparing measured magnetic field data values from known damaged rotor bars to the maximum and minimum values for the associated rotors, such as 10% of an average value, 10% of a maximum value and so forth. The algorithm then proceeds to 320.

At 320, a report is generated to indicate the location of damaged and broken rotor bars, such as to allow the location to be identified for repair, to allow service personnel to rotate the rotor to a position corresponding to a damaged or broken rotor bar or for other suitable purposes.

Although algorithm 300 is shown as a flow chart, the order of steps is exemplary and can be modified, supplemented or reduced as needed. In addition, algorithm 300 can be implemented as a state diagram, using object oriented programming or in other suitable manners.

FIG. 4 is a diagram 400 of a magnetic field measurement waveform in accordance with an exemplary embodiment of the present disclosure. As shown in diagram 400, the magnetic field strength varies in a roughly sinusoidal manner as a function of angular position. The 100% line shows the average maximum value, and the 80%, 20% and 10% lines show the corresponding 80%, 20% and 10% levels of the average maximum. The angular position of the six rotor bars is 0, 60, 120, 180, 240 and 300 degrees. Based on stochastically determined values of 80%, 20% and 10% levels of the average maximum, it can be seen that bar 2 would be indicated to be damaged, and bar 5 would be indicated to be broken. The analysis algorithms can use the magnetic field strength measurements as a function of angular position to determine the position of each rotor bar and whether the rotor bar is damaged or broken, as shown in the exemplary embodiment of diagram 400, such as by comparing the magnetic field strength measured at a given angular position with the magnetic field strength measured within an angular range equal to 360 divided by the number of rotor bars, by determining a series of peak values of magnetic field strength and the angular position between each peak, by comparing the maximum and minimum magnetic field strength measurements for each rotor bar to the average values for all rotor bars, or in other suitable manners.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. A system for magnetic field testing comprising:
a magnetic field generation device configured to generate a magnetic field in a rotor;
a magnetic field measurement device configured to measure a magnetic field at a predetermined position on the rotor;
a drive mechanism configured to rotate the rotor; and
a test system configured to record the magnetic field as a function of an angular position of the rotor.
